(19) United States
(12) Patent Application Publication
(10) Pub. No.: US 2013/0065332 A1
(43) Pub. Date: Mar. 14, 2013

(54) METHOD FOR MANUFACTURING LED WITH AN ENCAPSULANT HAVING A FLAT TOP FACE

(71) Applicants: HSIN-CHIANG LIN, Hsinchu (TW); WEN-LIANG TSENG, Hsinchu (TW)

(72) Inventors: HSIN-CHIANG LIN, Hsinchu (TW); WEN-LIANG TSENG, Hsinchu (TW)

(73) Assignee: ADVANCED OPTOELECTRONIC TECHNOLOGY, INC., Hsinchu Hsien 303 (TW)

(21) Appl. No.: 13/593,473

(22) Filed: Aug. 23, 2012

(30) Foreign Application Priority Data
Sep. 9, 2011 (CN) 201110267396.2

(51) Int. Cl. H01L 33/52; H01L 33/50

(52) U.S. Cl. 438/27; 438/28; 257/E33.059

(57) ABSTRACT

A method for manufacturing LEDs is disclosed. A base is firstly provided. The base includes a plate, sidewalls formed on the plate and pairs of leads connected to the plate. The sidewalls enclose cavities above the plate. Light emitting chips are fixed in the cavities and electrically connected to the leads, respectively. Encapsulants are formed in the cavities to seal the light emitting chips. Each encapsulant has a convex top face protruding beyond top faces of the sidewalls. The convex top faces of the encapsulants are grinded to become flat. Finally, the base is cut to form individual LEDs.

### BACKGROUND

1. Technical Field

The present disclosure relates to a method for manufacturing light emitting devices, and more particularly, to a method for manufacturing LEDs (light emitting diodes) with flat light emergent faces.

2. Description of Related Art

As a new type of light source, LEDs are widely used in various applications. An LED often includes a base having a cavity defined therein, a pair of leads fixed in the base, a light emitting chip received in the cavity to electrically connect the two leads, and an encapsulant filling the cavity to seal the chip. Typically, the encapsulant is formed in the cavity by injecting an encapsulation liquid into the cavity and then heating the liquid to become cured and solid. Thus, the encapsulant becomes rigid to form a light emergent face of the LED which is located at a top thereof. Usually, during conversion from liquid to solid, the encapsulant contracts, whereby the light emergent face is recessed. Thus, a concave light emergent face is naturally formed after the encapsulant is cured. The concave light emergent face affects the light emergent angle of the LED and causes the light distribution of the LED becoming undesirable. More specifically, the concave light emergent face lowers the intensity of light output from the LED.

What is needed, therefore, is a method for manufacturing LEDs which can overcome the limitations described above.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 shows a first step of a method for manufacturing LEDs in accordance with a first embodiment of the present disclosure.

FIG. 2 shows a second step of the method for manufacturing the LEDs in accordance with the first embodiment of the present disclosure.

FIG. 3 shows a third step of the method for manufacturing the LEDs in accordance with the first embodiment of the present disclosure.

FIG. 4 shows a fourth step of the method for manufacturing the LEDs in accordance with the first embodiment of the present disclosure.

FIG. 5 shows the LEDs which have been manufactured after the steps of FIGS. 1-4.

FIG. 6 shows one LED of FIG. 5 being further treated to have a rough light emergent face.

FIG. 7 shows a semi-finished product after several steps of a method for manufacturing LEDs in accordance with a second embodiment of the present disclosure.

FIG. 8 shows a next step of the method for manufacturing the LED, using the semi-finished product of FIG. 7.

FIG. 9 shows a next step of the method for manufacturing the LED after the step of FIG. 8.

FIG. 10 shows the LEDs which have been manufactured after the step of FIG. 9.

### DETAILED DESCRIPTION OF THE EMBODIMENTS

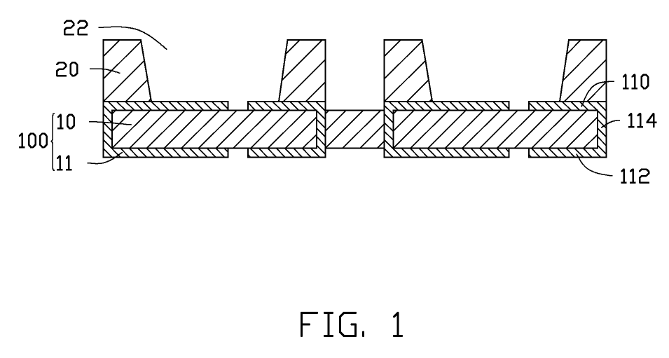

Referring to FIGS. 1-5, a method for manufacturing LEDs in accordance with a first embodiment of the present disclosure is shown. The method mainly includes several steps as discussed below.

Firstly, a base 100 is provided as shown in FIG. 1. The base 100 includes flat plate 10 and a plurality of pairs of leads 11 formed on the plate 10. A plurality of sidewalls 20 are formed on the plate 10. In this embodiment, the plate 10 and the sidewalls 20 are integrally made of a single monolithic piece of electrically-insulative materials such as epoxy or ceramic. Preferably, the plate 10 and the sidewalls 20 are made of polyphthalamide (PPA). Each sidewall 20 encloses a cavity 22 above the top face of the plate 10. The cavity 22 gradually expands along a bottom-to-top direction of the LED. The cavity 22 has a top opening (not labeled) communicating with an outside environment. Each pair of leads 11 is located corresponding to each sidewall 20. Each pair of leads 11 includes two leads 11 (i.e., a left lead 11 and a right lead 11) spaced from each other. Each lead 11 includes a top section 110 attached to the top face of the plate 10, a bottom section 112 attached to a bottom face of the plate 10, and a middle section 114 interconnecting the top section 110 and the bottom section 112. The bottom section 112 is parallel to the top section 110, and perpendicular to the middle section 114. The top sections 110 of each pair of leads 11 have inner ends exposed in a corresponding cavity 22.

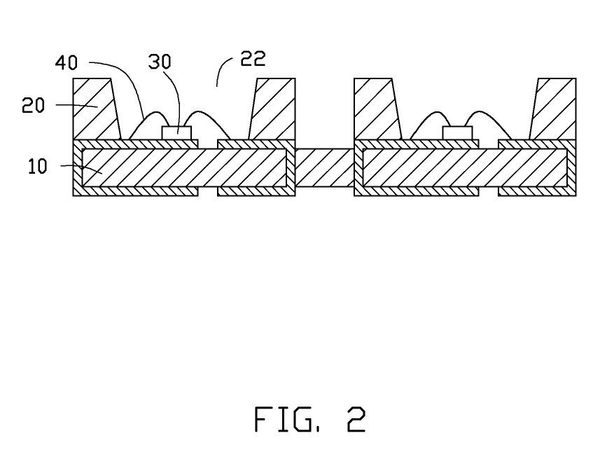

Also referring to FIG. 2, a plurality of light emitting chips 30 are then mounted in the cavities 22, respectively. Each light emitting chip 30 is fixed on the exposed inner end of the left lead 11 by adhesive (not shown) or other suitable methods such as eutectic bonding. Each light emitting chip 30 is electrically connected to the exposed inner ends of a corresponding pair of leads 11 through two wires 40. Each light emitting chip 30 can emit light by power transmitted from the corresponding pair of leads 11 and the wires 40.

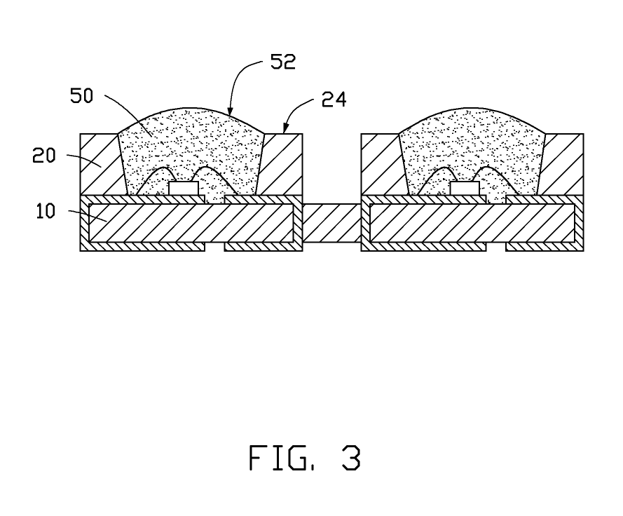

Also referring to FIG. 3, a plurality of encapsulants 50 are formed in the cavities 22 to seal the light emitting chips 30. Each encapsulant 50 may be formed by injecting a transparent liquid material (such as epoxy, silicone) into a corresponding cavity 22, and then cured to harden. Each encapsulant 50 fills the cavity 22 and has a convex top face 52 protruding upwardly beyond a top face 24 of an adjacent sidewall 20. The formation of the convex configuration of the encapsulant 50 is obtained since extra encapsulant which is more than necessary is injected into the cavity 22. Phosphors (not labeled) may be doped within the encapsulant 50 for changing color of the light emitted from the light emitting chip 30.

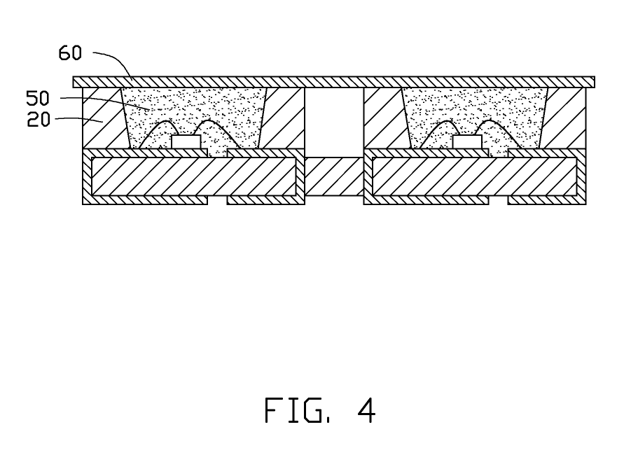

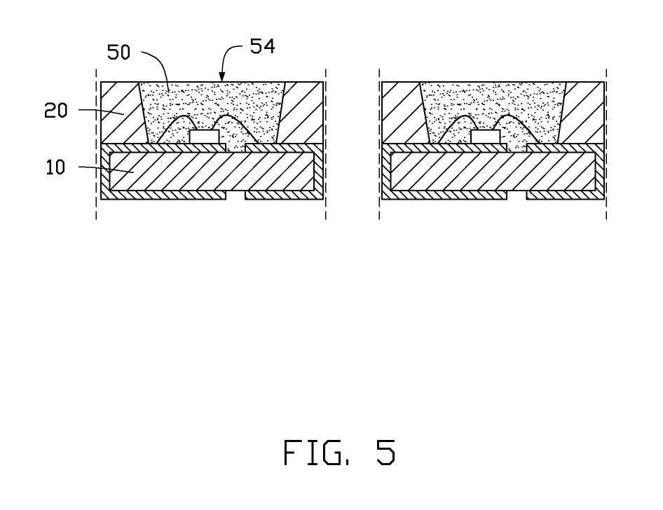

The encapsulants 50 are treated to become flat as shown in FIG. 4. The treating method of the encapsulants 50 includes providing a grinding tool 60 such as a rotating grinding wheel to grind the convex top faces 52 of the encapsulants 50 downwardly, until the grinding tool 60 reaching the top faces 24 of the sidewalls 20. The grinding tool 60 is then removed from the encapsulants 50. As a result, the convex top faces 52 of the encapsulants 50 are removed and new top faces 54 (see FIG. 5) of the encapsulants 50 are formed which are flat and smooth. The flat top faces 54 of the encapsulants 50 can ensure the light emitted from the light emitting chips 30 to have a satisfied intensity and light field.

Finally, as shown in FIG. 5, the plate 10 of the base 100 is cut at positions between every two adjacent sidewalls 20. Therefore, a plurality of individual LEDs are formed.

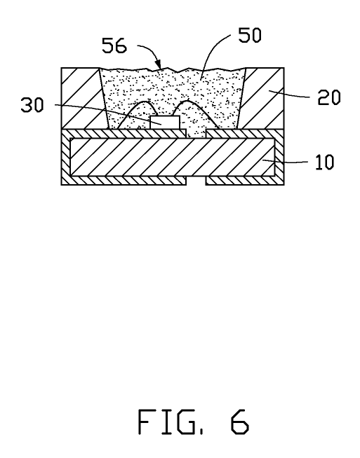

Alternatively, as shown in FIG. 6, the flat and smooth top face 54 of the encapsulants 50 can be further processed to be a flat and rough top surface 56. The flat and rough top surface 56 can have a patterned structure such as tiny protrusions formed thereon, by which light extraction efficiency of the LED can be increased. The patterned structure can be formed by a hot pressing of a mold on the flat and smooth top surface 54 of the encapsulant 50. A bottom face of the mold which is used to form the patterned structure of the flat, rough top surface 56 has a complementary patterned-structure.

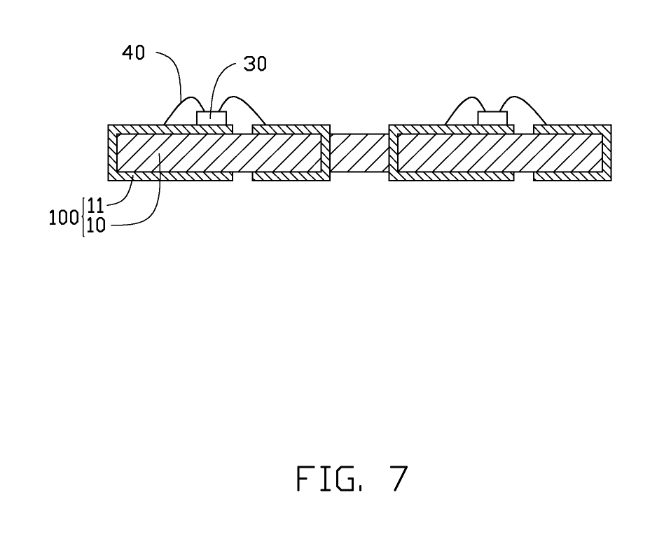

FIGS. 7-10 shows another method for manufacturing LEDs in accordance with a second embodiment of the present disclosure. Referring to FIG. 7, different from the base 100 of the first embodiment, the base 100 of the second embodiment does not have sidewalls 20 integrally formed with a plate 10 thereof. The base 100 of the second embodiment also includes a plurality of pairs of leads 11 formed on the plate 10 thereof. A plurality of light emitting chips 30 are fixed on the leads 11 and electrically connected to the leads 11 via wires 40.

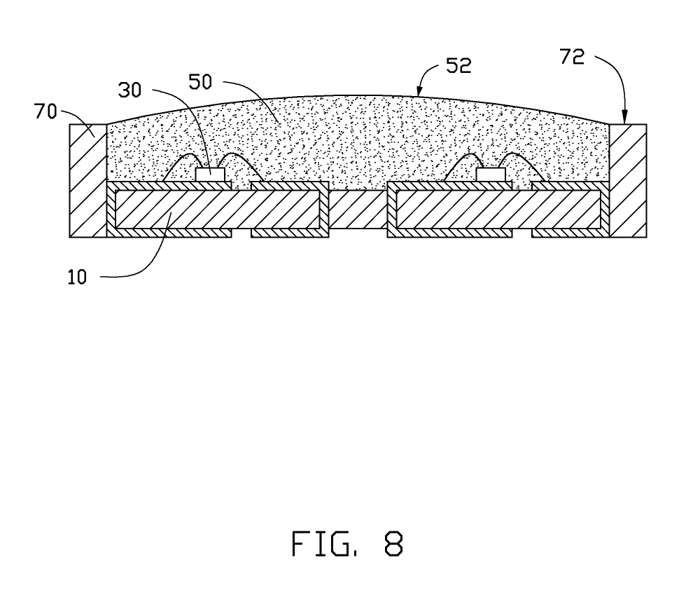

Also referring to FIG. 8, a plurality of sidewalls 70 are then mounted to the base 100 in a manner that each sidewall 70 abuts against a lateral side of a corresponding lead 11 located on an end of the base 100 or a front or rear side (not visible in FIG. 8) of the plate 10. Thus, the sidewalls 70 cooperatively enclose a cavity (not labeled) above a top face of the plate 10 of the base 100. An encapsulation liquid further fills the cavity to form an encapsulant 50 sealing the light emitting chips 30 and the wires 40. The encapsulant 50 has a convex top face 52 protruding upwardly beyond top faces 72 of the sidewalls 70. Phosphors (not labeled) may be further doped within the encapsulant 50 to change color of light emitted from the light emitting chips 30.

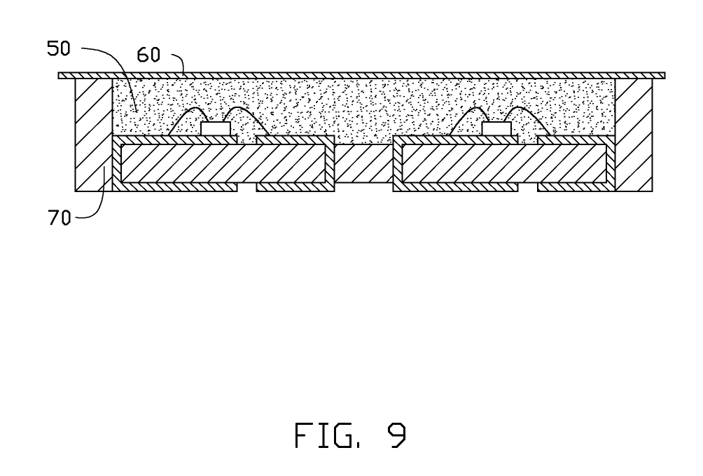

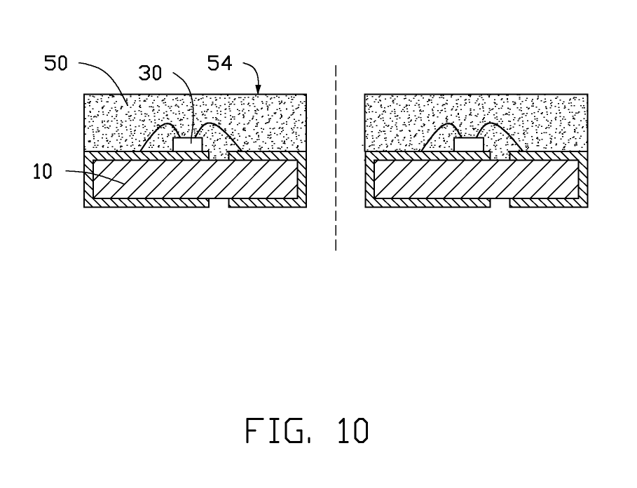

The convex top face 52 of the encapsulant 50 is then flattened through a grinding tool 60 as shown in FIG. 9. The grinding tool 60 gradually grinds the convex top face 52 of the encapsulant 50 away until the grinding tool reaches the top faces 72 of the sidewalls 70. The grinding tool 60 and the sidewalls 70 are then removed from the encapsulant 50 to expose the encapsulant 50. Thus, a new top face 54 (see FIG. 10) of the encapsulant 50 is obtained which is flat and smooth. Alternatively, the flat and smooth top face 54 may also be further processed to be flat and rough for extracting more light from the LEDs.

Finally, the base 100 is cut at positions between every two adjacent pairs of leads 11 as shown in FIG. 10. Thus, a plurality of individual LEDs are formed.

It is believed that the present disclosure and its advantages will be understood from the foregoing description, and it will be apparent that various changes may be made thereto without departing from the spirit and scope of the present disclosure or sacrificing all of its material advantages, the examples hereinbefore described merely being preferred or exemplary embodiments.

What is claimed is:

1. A method for manufacturing LEDs (light emitting diodes), comprising:
providing a base comprising a plate and a plurality of pairs of leads connecting the plate, a plurality of light emitting chips being electrically connected to the leads, respectively;
providing a plurality of sidewalls enclosing the light emitting chips;
forming an encapsulant surrounded by the sidewalls and sealing the light emitting chips, the encapsulant having a convex top face protruding beyond top faces of the sidewalls;
flattening the convex top face of the encapsulant; and
cutting the base to form individual LEDs.

2. The method of claim 1, wherein the convex top face of the encapsulant is flattened by using a grinding tool to grind the convex top face of the encapsulant until the grinding tool reaches the top faces of the sidewalls.

3. The method of claim 2, wherein the encapsulant is formed by injecting an encapsulation liquid to cover the light emitting chips, and then curing the encapsulation liquid to harden.

4. The method of claim 3, wherein the grinding tool grinds the convex top face of the encapsulant after the encapsulant is hardened.

5. The method of claim 1, wherein the sidewalls are made integrally with the plate as a single monolithic piece.

6. The method of claim 1, wherein the sidewalls are separably engaged with the base by abutting against lateral sides of the base.

7. The method of claim 6, wherein the sidewalls abut against lateral sides of the leads located at ends of the base.

8. The method of claim 6, wherein the sidewalls are removed from the base after the convex top face of the encapsulant is flattened.

9. The method of claim 1, wherein each sidewall encloses a cavity to receive a corresponding light emitting chip therein before forming the encapsulant, the encapsulant comprising a plurality of encapsulant portions received in the cavities, respectively.

10. The method of claim 9, wherein each sidewall is located just above a corresponding pair of leads.

11. The method of claim 1, wherein the sidewalls cooperatively enclose a single cavity to receive the light emitting chips therein before forming the encapsulant.

12. The method of claim 1, wherein each light emitting chip is bonded on a corresponding lead.

13. The method of claim 12, wherein each light emitting chip is electrically connected to the corresponding lead and an adjacent lead via two wires.

14. The method of claim 1, wherein the flattened top face of the encapsulant is smooth.

15. The method of claim 1, wherein the flattened top face of the encapsulant is rough.

16. The method of claim 1, wherein the base is cut at positions between every two adjacent pairs of leads.

17. The method of claim 1, wherein the encapsulant has phosphors doped therein.
